(19) United States
(12) Patent Application Publication
(10) Pub. No.: US 2008/0078437 A1
(43) Pub. Date: Apr. 3, 2008

(54) SOLAR FARMS HAVING ULTRA-LOW COST OPV MODULES

(75) Inventor: Troy D. Hammond, Pittsburgh, PA (US)

Correspondence Address: FOLEY AND LARDNER LLP;SUITE 500, 3000 K STREET NW, WASHINGTON, DC, 20007, US

(73) Assignee: Plextronics, Inc.

(21) Appl. No.: 11/865,625

(22) Filed: Oct. 1, 2007

Related U.S. Application Data
(60) Provisional application No. 60/848,363, filed on Oct. 2, 2006.

(51) Int. Cl. H01L 31/042

(52) U.S. Cl. 136/244; 29/25.01

(57) ABSTRACT

Solar farms comprising solar panels and solar cells having limited efficiencies and lifetimes, but which are low cost and easily replaceable. Organic photoactive layers can be used including low molecular weight organic compounds and polymeric organic compounds including conducting polymers. Polythiophenes and regioregular polythiophenes are a preferred embodiment for the photoactive layer and can be coupled with fullerene compounds. Cost modeling can be carried out to prove the economic profitability of the solar farm. Levelized cost of energy can be calculated.

### RELATED APPLICATIONS

This application claims priority to U.S. provisional application Ser. No. 60/848,363 filed Oct. 2, 2006, which is hereby incorporated by reference in its entirety.

### BACKGROUND

Solar cells or photovoltaic devices have been proposed for large scale use in solar farms for harvesting light energy. In most cases, however, these farms have been conceived with use of materials which have as high energy conversion and quantum efficiency and lifetimes as possible. For example, US patent publication 2005/00828524 describes use of high-efficiency multi-junction photovoltaic cells.

Solar cell development generally can be divided into several generations of development. For example, first generation solar cells were made from large-area single layer p-n junction diode typically made of silicon. In a second generation, multiple layers can be used with each layer designed to absorb successively longer wavelengths. The third generation are semiconductor devices which can use for example dye sensitized cells, organic polymer cells, or quantum dot solar cells. More generally, thin film technologies include for example CdTe, CIGS, CIS, GaAs, light absorbing dyes, silicon, and organic/polymer solar cells.

Solar cells can be electrically connected and encapsulated as a module and called a photovoltaic array or a solar panel. Solar panels can have a sheet of glass on the front, sun side up and a resin barrier behind to protect the materials from the elements. Solar cells can be connected in series in modules creating an additive voltage. Solar panels based on crystalline or solar-grade silicon, c-Si, can be warranted for 25 years and should see 35 plus years of useful life.

The economic cost of electricity-generating systems can be calculated as a price per delivered kilowatt-hour. Economic models can be developed and software programs can be used to predict economic outcomes for solar farms. See for example (i) “Solar Advisor Model: User Guide for Solar America Initiative Technology Pathway Partnerships Applicants” Jun. 30, 2006, provided by NREL, (ii) “A Manual for the Economic Evaluation of Energy Efficiency and Renewable Energy Technologies,” National Renewable Energy Laboratory (NREL), March 1995, NREL Technical Publication 662-5173. The parameter “levelized cost of energy” (LCOE) can be used as a primary metric for comparing the cost of solar electricity against electricity generated by other methods.

While conductive polymers are recognized as potentially useful for solar cells, they are generally regarded in the art as unsuitable for large scale applications, including integrating with the power grid, because of low efficiency, short lifetimes, resulting in degradation and sensitivity to the environment. Therefore, conductive polymers and other solar active materials which have relatively low efficiencies and lifetimes generally have not been suggested or used for solar farms. Rather, a research push exists to find materials generating efficiencies of 50% or greater. Nevertheless, a need exists to continue to improve economic models for solar cell energy production and implementation of same. In particular, new applications are needed for organic-based photovoltaic devices (OPVs).

### SUMMARY

It has been recognized that the lowest cost in a solar farm, as measured in for example, LCOE, may not come from extending lifetime. Rather, ultra-low cost organic photovoltaic modules can be used in a solar farm system designed for ultra-low cost replacements, e.g., swap-in and swap-out.

The present embodiments encompass devices, systems, methods of making, and methods of using, as well as business methods.

Accordingly, one embodiment provides a solar farm comprising: a plurality of replaceable solar cell panels adapted to convert sunlight into electrical power, wherein the panels comprise solar cells having energy conversion efficiency of about 13% or less and a lifetime (T₅₀) of about 15 years or less. Another embodiment comprises a method of making a solar farm comprising: manufacturing a plurality of replaceable solar cell panels adapted to covert sunlight into electrical power, wherein the panels comprise solar cells having energy conversion efficiency of about 13% or less and a lifetime (T₅₀) of about 15 years or less. The embodiment can further comprise the step of assembling the manufactured replaceable solar cell panels into a solar farm.

Another embodiment provides a method comprising: providing a plurality of replaceable solar cell panels adapted to convert sunlight into electrical power, wherein the panels comprise solar cells having energy conversion efficiency of about 10% or less, exposing the solar cell panels to sunlight, replacing the solar cell panels with additional replaceable solar cell panels.

Advantages include improved economic recovery of investment.

### FIGURES

FIG. 1 illustrates solar farm model assumptions.

FIG. 2 illustrates solar farm LCOE versus time.

FIG. 3 illustrates a schematic for OPV mini-fab line development and manufacturing.

FIG. 4 illustrates calculating LCOE fro OPV.

FIG. 5 illustrates degradation impact on economics.

FIG. 6 shows optimized LCOE not necessarily longest lifetime.

### DETAILED DESCRIPTION

### Introduction

All references cited herein are incorporated by reference in their entireties.

Priority provisional application 60/848,363 filed Oct. 2, 2006 is hereby incorporated by reference in its entirety including the thirteen figures.

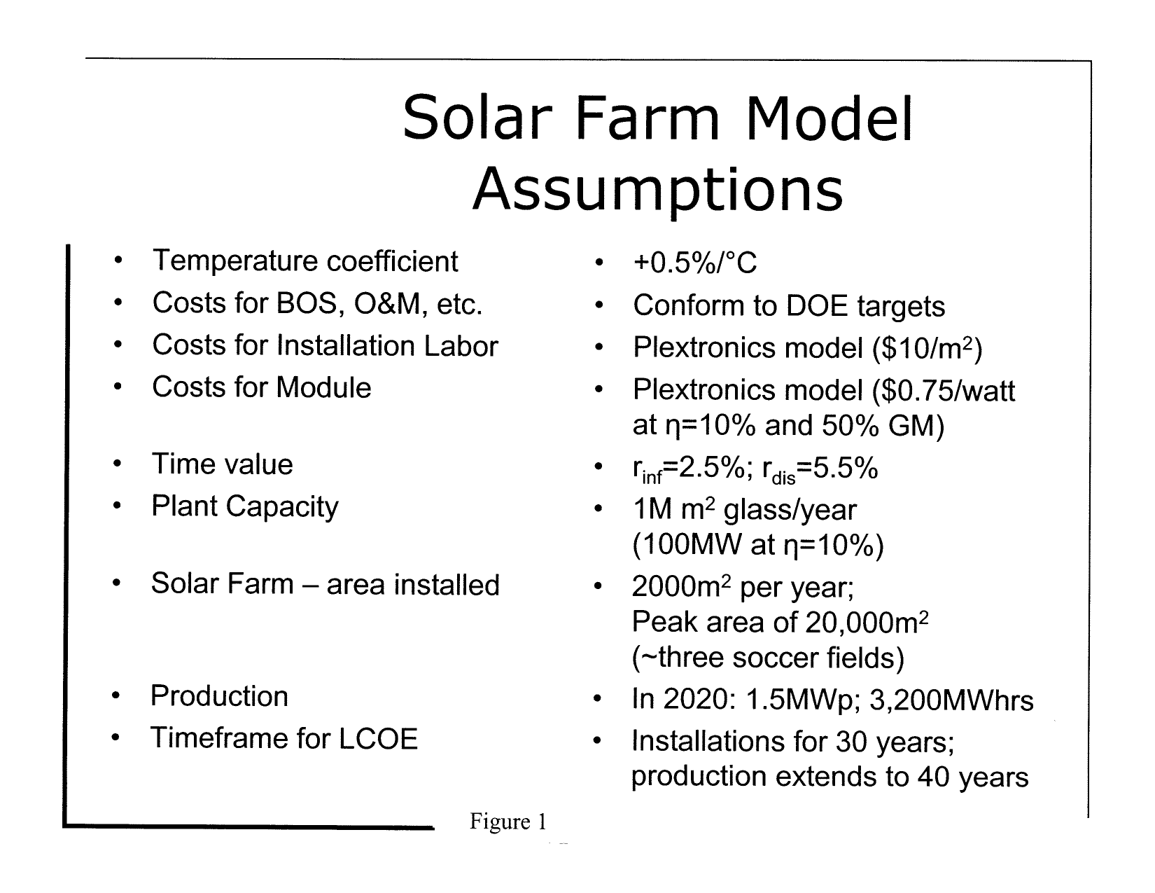

FIG. 1 of the priority provisional application 60/848,363 provides an overview for a technology improvement pathway based on the year 2006 as a starting point, going through the year 2015. It lists parameters including efficiency, MTBF, degradation, lifetime, and color, which are described further below. It also notes the target applications for commercialization including solar farm, solar window, and roof-top.

| | Year | | | |
|---|---|---|---|---|
| | 2006 | 2008 | 2012 | 2015 |
| Efficiency | 4% | 7% | 10% | 13% |
| MTBF | 1 yr | 5 yr | 10 yrs | 20 yrs |
| Year 1 | 50% | 40% | 30% | 20% |
| Degradation | | | | |
| Ongoing | — | 10%/yr | 5%/yr | 5%/yr |
| Degradation | | | | |
| Lifetime (T₅₀) | 1 yr | 3 yrs | 7 yrs | 10 yrs |
| Module Color | Red-ish | Blue-green | Neutral | transparent |

Solar cell panels or modules are well-known in the art and can be adapted to convert sunlight into electrical power. The panels or modules can comprise for example a plurality of unit solar cells, wherein each solar cell can be characterized by parameters known in the art including for example energy conversion efficiency and lifetime (T₅₀). For example, a solar panel or module can comprise a front side made of glass, interconnected solar cells, an embedding material, and rear-side structure. See for example U.S. Pat. No. 7,049,803. The glass front side can provide protection against mechanical and atmospheric influences. The glass can be adapted to provide suitable absorption and transmission. Additional examples of solar cell panels are described in for example U.S. Pat. Nos. 4,830,038 to Anderson et al.; 5,008,062 to Anderson et al.; and 4,638,111 and 4,461,922 to Gay. In general, encapsulation, packaging, stacking, electrical interconnects, and housing can be used to protect the solar cell components from environmental influences and production methods and integrate individual solar cells into a single panel or module.

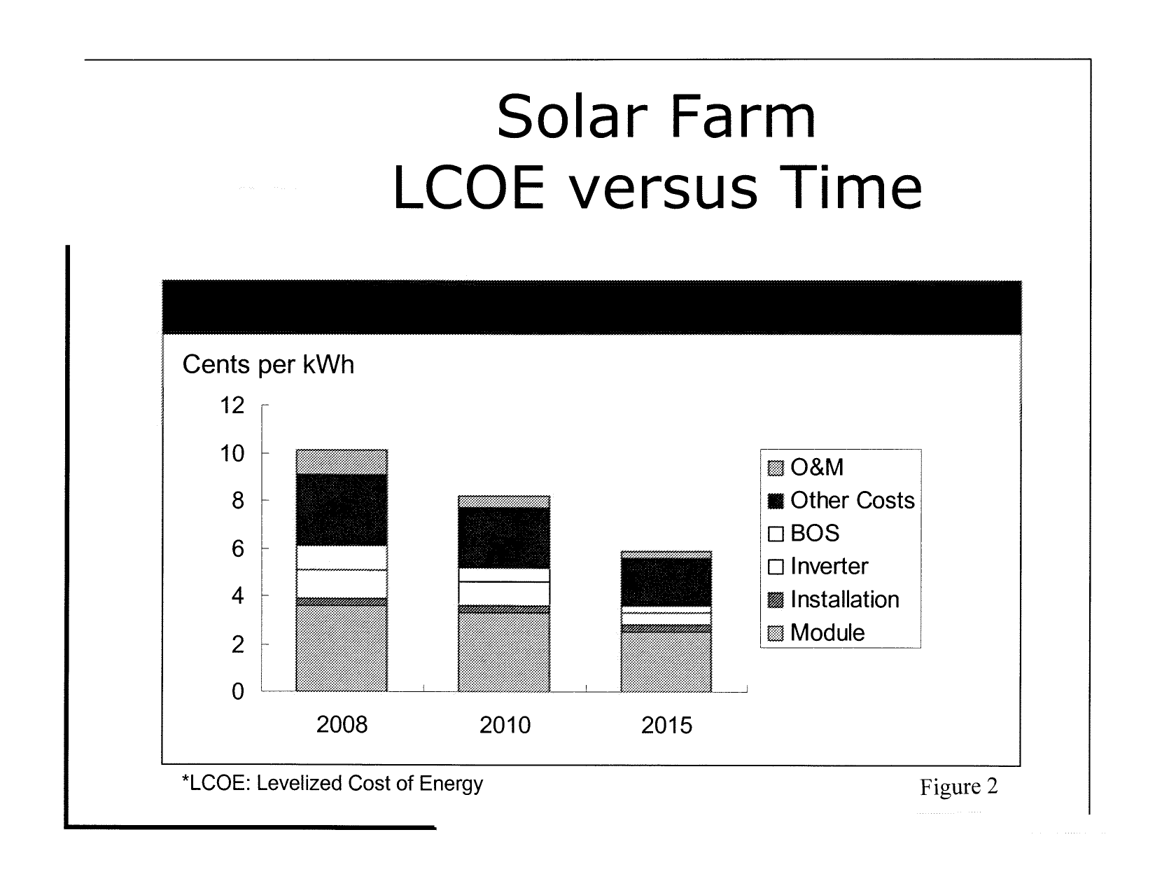

Solar farms are generally known in the art and can be larger scale commercial power production sites. An example is illustrated in FIG. 2 of the priority provisional application 60/848,363 including an aerial perspective. Solar farms can be used for example on roofs or open land.

The solar farm can employ methods known in the art such as for example raising and tilting solar panels to track the sun, concentrate the sunlight, convert DC to AC by inverters, store energy, and the like.

Solar cell materials are generally described in M. A. Green, Third Generation Photovoltaics; Advanced Solar Energy Conversion, Springer-Verlag, Berlin, 2004.

The overall system lifetime can be for example at least 35 years.

Panel or module size is not particularly limited but can be for example about 0.1 to about 100 square meter per module, or about 0.5 square meter per module to about 10 square meter per module, or about one square meter per module. One embodiment is, for example, a 6 inch by 6 inch embodiment, or a 1 meter by 1 meter embodiment, or a 3 meter×3 meter embodiment. Multiple solar cells can be used together in a module and electrodes can be adapted for use of multiple cells per module.

### Replaceable Solar Cell Panels

Replaceable solar cell panels can be fabricated by methods known in the art. Thin film solar cells can be made. Roll-to-roll printing can be carried out. Nanostructured materials can be used. The panels, alternatively called modules, can comprise active layer, electrodes, and packaging.

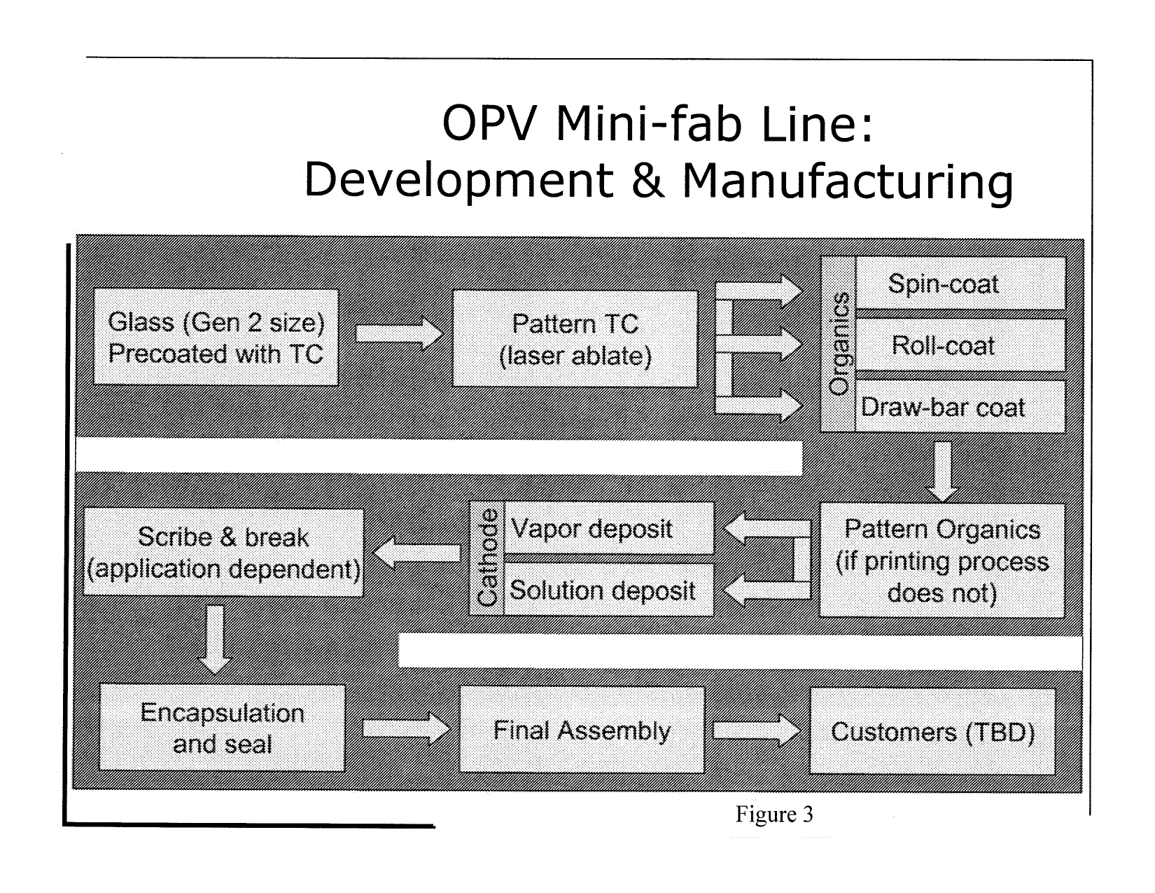

An illustrative method is provided in FIG. 3 (FIG. 10 of priority provisional 60/848,363). The process can begin with a glass substrate which can be coated with a transparent conductive material (TC) as anode. Patterning of the TC can be carried out. An organic component can be layered based on known coating processes like spin coating, roll coating, or draw bar coating. The organic layer can be patterned. A cathode layer can be fabricated by vapor or solution methods. Further scribing and breaking can be carried out depending on the application. Encapsulation and sealing can be carried out. In general, steps are executed to keep costs to a minimum so that the replaceable solar panel is inexpensive to use.

The panel is adapted to be easily, efficiently, and economically replacable. The panels are not permanently or semi-permanently affixed. Rather, they are impermanently affixed. The panel can be disposable in that it structurally is built to be replaced although it is stable enough to be used until in need of replacement. For example, the frame and power block can be adapted to enable low cost removal and insertion or connection of the low cost replacement. In one embodiment, manual replacement can be used without need for complicated or expensive or difficult to use tools. In contrast, solar cell panels in the prior art can be adapted for difficult replacement as easy replacement is not a goal.

The solar cells can be encapsulated with resins and films for example to shield UV radiation and minimize moisture and oxygen permeation.

Users of the panels can have for example open flat roofs or convenient ground space adjacent to a facility that presents minimal constraints to installation of a solar farm.

Photovoltaic modules or panels are generally known. See for example U.S. Pat. No. 6,329,588 to Zander et al.; U.S. Pat. No. 6,391,458 to Zander et al.; U.S. Pat. No. 7,049,803 to Dorner et al. Large-area photovoltaic cells are generally known. See for example U.S. Pat. No. 4,385,102 to Fitzky et al.

### Organic Photovoltaics

The photoactive layer can comprise for example p-type and n-type materials to form bulk heterojunctions.

The photoactive layer can comprise organic compound including low molecular weight compounds, polymers, or a combination thereof.

Organic conducting or conjugated polymers can be used in the photoactive layer. For example, regioregular polymers such as polythiophenes can be used. See for example U.S. Pat. Nos. 6,602,974 and 6,166,172 to McCullough et al., and US Patent Publication 2006/0076050 to Williams et al. See also U.S. provisional application 60/776,213 to Laird et al. filed Feb. 24, 2006 (High Performance Polymer Photovoltaics) and U.S. regular application Ser. No. 11/376,550 to Williams et al. filed Mar. 16, 2006 (Copolymers of Soluble Polythiophenes with Improved Electronics Performance). See also materials available from Plextronics (Pittsburgh, Pa.).

Materials like fullerenes can be also used such as for example blends of conducting polymer and soluble fullerene derivative like PCBM. See for example U.S. application Ser. No. 11/743,587 to Laird et al. filed May 2, 2007 and also U.S. provisional application 60/812,961 to Laird et al. filed Jun. 13, 2006, “ORGANIC PHOTOVOLTAIC DEVICES COMPRISING FULLERENES AND DERIVATIVES THEREOF.” Efficiencies greater than 5% can be achieved. An example of the conducting polymer is poly(3-alkylthiophene) including for example poly(3-hexylthiophene). The n-type and p-type materials can be energetically matched. Electron-withdrawing groups can be attached to a fullerene compound. C60 or C70 or C84 or carbon nanotube compounds and C60 and C70 or C84 or carbon nanotube derivative compounds can be used. Materials including nanostructured carbon materials can be obtained from for example Nano-C, Inc. (Westwood, Mass.). Carbon nanotubes can be single walled, double walled, or multi-walled.

Also, printed solar panels are described in US Patent publication 2005/0247340 to Zeira et al.

### Other Components

Hole injection and hole transport layers can be used. Examples of hole injection materials include US patent publication 2006/0175582 to Hammond et al. (Hole Injection Layer Compositions) and U.S. provisional application 60/832,095 filed Jul. 21, 2006 to Seshadri et al. (Sulfonated Conducting Polymers . . . ). While Baytron PEDOT:PSS can be used, acidity can be a problem with this material.

Electrodes can be anodes and cathodes. Anodes can be transparent conductive oxides such as for example indium tin oxide. The cathode can be bilayer including for example Ca/Al or LiF/Al, as well as LiF/Ca/Al and Mg/Ag. Low reactivity single layer cathodes can be used such as Al, Mg, Ag. Solution or vacuum methods of fabrication can be used. Post-production cathode treatments can be carried out.

Packaging materials can comprise for example sealant and adhesive.

Substrates can be used.

Pixels can be used.

The below table includes an overview of module layers and function.

Top substrate/laminate & barrier
Top electrode
Active layers
Transparent electrode
Substrate, barrier & antireflection
Coating for UV protection

### Efficiency

The energy conversion efficiency (η, eta) can be for example about 13% or less, or about 10% or less, or about 7% or less, or about 4% or less. This value is the percentage of power converted, from absorbed light to electrical energy, and collected when a solar cell is connected to an electrical circuit. This can be expressed by:

η=Pₘ/E×A_{c}

### Wherein Pₘ is the maximum power point in watts, E is the input light irradiance under standard test conditions (W/m²), and A_{c} is the surface area of the solar cell (square meters).

In practice, energy conversion efficiency can be measured by short-circuit current density (J_{sc}=I_{sc}/A_{c}) and voltage analysis of a solar cell where voltage is swept from 0 to V_{oc} of the device under dark and AM1.5G (one sun, 1000 W/m²) illumination. The area of the pixel can be determined for precise estimation of device current density. From the collected data the solar cell parameters V_{oc} (open circuit voltage), J_{sc}, and FF (Fill Factor) can be determined. The energy efficiency is simply equal to [(J_{sc}×V_{oc}×FF)/100 mW/cm²].

### Lifetime

The lifetime (T₅₀) can be for example about 15 years or less, or about 10 years or less, or about 7 years or less, or about 3 years or less, or about one year or less. Lifetime T₅₀ can be measured by the time it takes for the efficiency to be degraded to half the initial efficiency. For example, an original efficiency of 5% can be degraded to 2.5%, and the time for that degradation to take place can be measured.

### Area

The solar farm can be built for large scale power production with large area modules. The area means that surface of the module on which when light is incident gets coupled into the thin films comprising the actual device. For example, the area can be at least 500 square meters or more, or about 1,000 square meters or more, or about 4,000 square meters or more, or about 10,000 square meters or more.

The solar farm can have a capacity for yearly production of at least about 50 MWh, or at least about 100 MWh, or at least about 1,000 MWh, or at least about 2,000 MWh, or at least about 5,000 MWh, or at least about 10,000 MWh.

### MTBF

Another parameter is mean time between failure (MTBF). This is measured by testing of several modules under similar and different testing conditions from which a lifetime under normal operating conditions is determined. The value predicted from all the modules will not agree consistently and, hence, a mean time is reported as the expected lifetime of the module.

### Degradation

Other parameters related to degradation. For example, year one degradation means a reduction of power generated by the module due to a reduction in open circuit voltage, short circuit current and fill factor. One year degradation can be for example at least about 5%, or at least about 10%, or at least about 20%. Ongoing degradation means degradation of individual cell performance combined with losses in power due to problems with interconnect as well as degradation of encapsulation.

### Module Color

Module color is another parameter. For example, modules can be reddish or blue-green. This can be important because this is an indicator of the portion of the solar spectrum from which light is being effectively absorbed by the active layer. This determines the total number of photons which can be harvested to generate photocurrent. The color can be also neutral.

### ADDITIONAL EMBODIMENTS

Embodiments described herein can include ultra-low cost OPV modules, used in a context of technology which is improving rapidly, but wherein fast degradation is yet experienced. A system can be generated which is adapted for ultra-low cost swap-in/swap-out. In this embodiment, lowest cost is not coming from extended lifetime. In this embodiment, modules can be replaced at economic optimal points, e.g., η=50%.

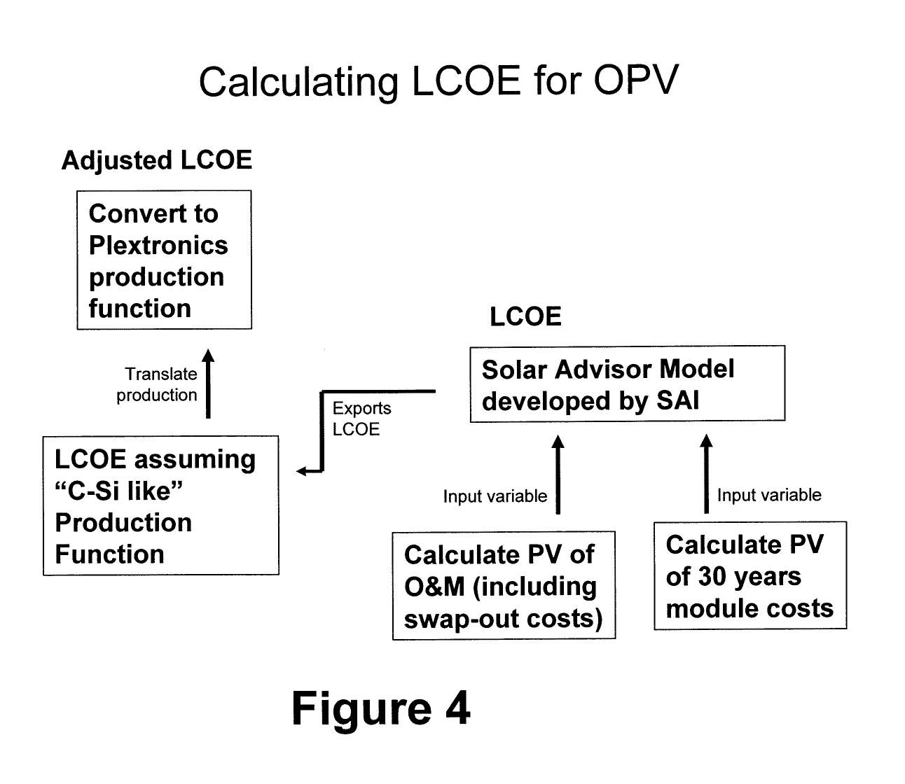

FIG. 4 of priority provisional 60/848,363 shows yearly production trends as part of solar farm output.

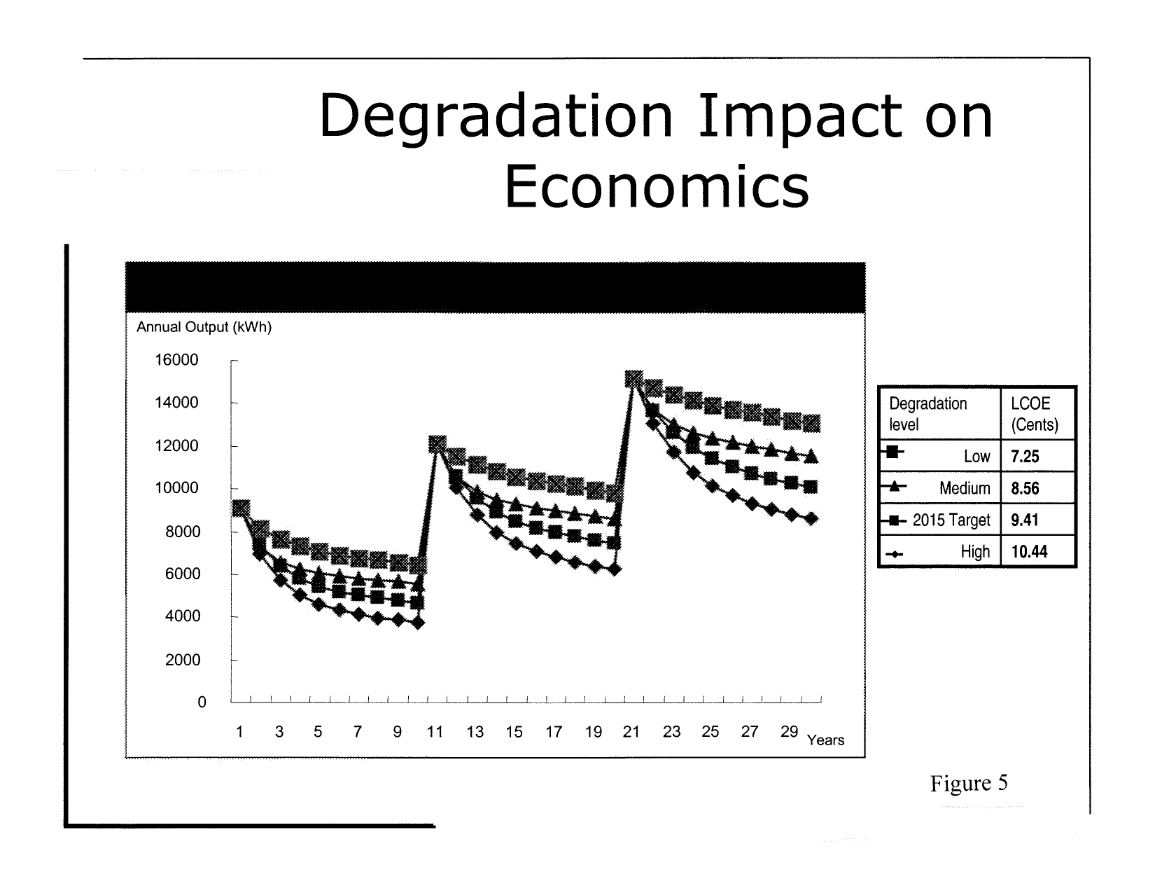

FIG. 5 of priority provisional 60/848,363 shows installed peak capacity per year.

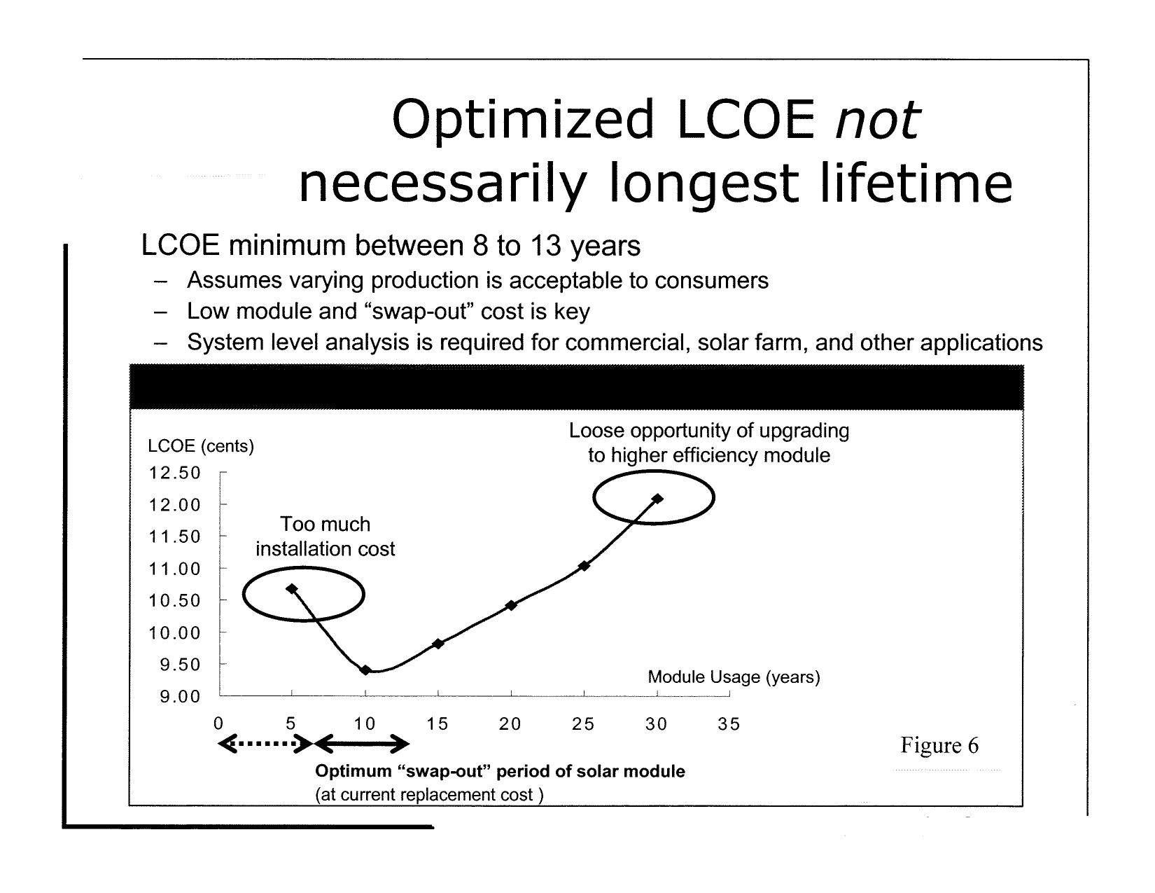

FIG. 6 of priority provisional 60/848,363 shows installed solar cell area per year.

FIG. 7 of priority provisional 60/848,363 shows solar farm costs per year.

FIG. 8 of priority provisional 60/848,363 shows “captive Pennsylvania market” at 800 MW of solar photovoltaic.

What is claimed is:

1. A solar farm comprising:
a plurality of replaceable solar cell panels adapted to convert sunlight into electrical power, wherein the panels comprise solar cells having energy conversion efficiency of about 13% or less and a lifetime (T₅₀) of about 15 years or less.

2. The solar farm according to claim 1, wherein the energy conversion efficiency is about 10% or less.

3. The solar farm according to claim 1, wherein the energy conversion efficiency is about 7% or less.

4. The solar farm according to claim 1, wherein the energy conversion efficiency is about 4% or less.

5. The solar farm according to claim 1, wherein the lifetime is about 10 years or less.

6. The solar farm according to claim 1, wherein the lifetime is about 7 years or less.

7. The solar farm according to claim 1, wherein the lifetime is about 3 years or less.

8. The solar farm according to claim 1, wherein the solar farm has a solar farm area of about 500 square meters or more.

9. The solar farm according to claim 1, wherein the solar farm has a solar farm area of about 4,000 square meters or more.

10. The solar farm according to claim 1, wherein the solar farm has a solar farm area of about 10,000 square meters or more.

11. The solar farm according to claim 1, wherein the solar farm has capacity for yearly production of at least about 50 MWh.

12. The solar farm according to claim 1, wherein the solar farm has capacity for yearly production of at least about 100 MWh.

13. The solar farm according to claim 1, wherein the solar farm has capacity for yearly production of at least about 2,000 MWh.

14. The solar farm according to claim 1, wherein the solar cells comprise active layers comprising organic compound.

15. The solar farm according to claim 1, wherein the solar cells comprise active layers comprising polymeric organic compound.

16. The solar farm according to claim 1, wherein the solar cells comprise active layers comprising conjugated polymeric organic compound.

17. The solar farm according to claim 1, wherein the solar cells comprise active layers comprising polythiophene organic compound.

18. The solar farm according to claim 1, wherein the energy conversion efficiency is about 10% or less and the lifetime is about 7 years or less.

19. The solar farm according to claim 1, wherein the energy conversion efficiency is about 7% or less and the lifetime is about 3 years or less.

20. The solar farm according to claim 1, wherein the energy conversion efficiency is about 4% or less and the lifetime is about 1 year or less.

21. The solar farm according to claim 1, wherein the energy conversion efficiency is about 10% or less and the lifetime is about 7 years or less, and the solar farm has a solar farm area of about 1,000 square meters or more, and wherein the solar cells comprise active layers comprising organic compound.

22. A method of making a solar farm comprising:
manufacturing a plurality of replaceable solar cell panels adapted to covert sunlight into electrical power, wherein the panels comprise solar cells having energy conversion efficiency of about 13% or less and a lifetime (T₅₀) of about 15 years or less.

23. The method according to claim 22, further comprising the step of assembling the manufactured replaceable solar cell panels into a solar farm.

24. A method comprising:
providing a plurality of replaceable solar cell panels adapted to convert sunlight into electrical power, wherein the panels comprise solar cells having energy conversion efficiency of about 10% or less,
exposing the solar cell panels to sunlight,
replacing the solar cell panels with additional replaceable solar cell panels.

25. A system comprising:
a plurality of replaceable solar cell panels adapted to convert sunlight into electrical power, wherein the panels comprise solar cells having energy conversion efficiency of about 13% or less and a lifetime (T₅₀) of about 15 years or less, the solar cell panels adapted to function as a solar farm.

26. A solar farm comprising:
a plurality of replaceable solar cell panels adapted to convert sunlight into electrical power, wherein the panels comprise solar cells having mean time between failure MTBF of about 20 years or less.

27. A solar farm comprising:
a plurality of replaceable solar cell panels adapted to convert sunlight into electrical power, wherein the panels comprise solar cells having a one year degradation of at least 5%.

28. The solar farm according to claim 27, wherein the cells have a one year degradation of at least 10%.

29. The solar farm according to claim 27, wherein the cells have a one year degradation of at least 20%.

30. A solar cell panel comprising:
a plurality of solar cells having energy conversion efficiency of about 13% or less and a lifetime (T₅₀) of about 15 years or less, the solar cell panels adapted to be replaceable.

31. A solar farm comprising:
a plurality of replaceable solar cell panels adapted to convert sunlight into electrical power, wherein the panels comprise solar cells having energy conversion efficiency of about 13% or less and a lifetime (T₅₀) of about 15 years or less, and wherein the replaceable solar cell panels are adapted to be replaced by panels comprising solar cells having energy conversion efficiency of about 13% or less and a lifetime (T₅₀) of about 15 years or less.
